(19) United States
(12) Patent Application Publication
(10) Pub. No.: US 2014/0211531 A1
(43) Pub. Date: Jul. 31, 2014

(54) LIQUID COOLING TYPE POWER CONVERSION APPARATUS AND RAILWAY VEHICLE

(71) Applicant: Kabushiki Kaisha Toshiba, Tokyo (JP)

(72) Inventors: Mitsuyo YAMASHITA, Tokyo (JP); Yuuji IDE, Tokyo (JP)

(21) Appl. No.: 14/225,030

(22) Filed: Mar. 25, 2014

Related U.S. Application Data
(63) Continuation of application No. PCT/JP2012/003469, filed on May 28, 2012.

(30) Foreign Application Priority Data
Sep. 26, 2011 (JP) 2011-209994

(51) Int. Cl. H05K 7/20

(52) U.S. Cl. CPC H05K 7/20154; H05K 7/20263
USPC 363/141; 361/696; 361/690

(57) ABSTRACT

According to one embodiment, a liquid cooling type power conversion apparatus is provided. The liquid cooling type power conversion apparatus has a power conversion apparatus and a cooling apparatus which are provided in an engine room of a railway vehicle, an electric component and a plurality of semiconductor devices which are provided in the power conversion apparatus, a third heat exchanger located between the electric component and an electric blower, a cooling body on which the plurality of the semiconductor devices are mounted, a first heat exchanger provided in the cooling apparatus, a second heat exchanger provided in the cooling apparatus having a size smaller than the first heat exchanger 111b, a piping to connect the third heat exchanger 5 and the second heat exchanger, and a piping to connect the cooling body and the first heat exchanger.

### CROSS-REFERENCE TO RELATED APPLICATION

This application is based upon and claims the benefit of priority from the prior Japanese Patent Application No. 2011-209994, filed on Sep. 26, 2011; the entire contents of which are incorporated herein by reference. This application is a continuation application of International Patent Application No. PCT/JP2012/003469, filed on May 28, 2012.

### FIELD

Embodiments described herein relate to a liquid cooling type power conversion apparatus and a railway vehicle.

### BACKGROUND

Generally, a railway vehicle is supplied with power from an overhead line, and a power conversion apparatus for a railway vehicle converts the power into power capable of driving a motor installed on the vehicle. The motor receives the converted power, and rotates, and thereby the vehicle can run on a railroad. In the above-described power conversion apparatus for railway, a semiconductor module composed of semiconductor devices and an electric component that is a peripheral circuit thereof is incorporated. The power conversion apparatus performs power conversion by the switching operation of the semiconductor devices. Since the switching operation of the semiconductor devices generates much heat loss, cooling technology which effectively discharges this heat to the outside of the power conversion apparatus, and keeps the temperature of the semiconductor devices within an operation allowable temperature range becomes necessary.

In the power conversion apparatus, in addition to the above-described semiconductor module, an electric device, such as a blower and a control device, is housed, and heat loss is generated from this electric device. By this heat loss, the temperature in an apparatus chamber and the power conversion apparatus rises, and thereby the installed electric device is exposed to high temperature environment. The electric device is not used within the operating temperature range for normal operation, to cause a fault, and the life thereof becomes shorter than the estimated time. For the reason, in order to protect the semiconductor module and the electric device which are housed in the power conversion apparatus for a railway vehicle, the temperature rise must be suppressed.

As technology necessary for cooling a semiconductor device, there are a heat receiving portion to receive the heat loss generated from the semiconductor device, and a radiating portion to discharge this heat loss to the outside of the semiconductor module. As a method of cooling this radiating portion, there is a liquid cooling system. This cooling system connects between a heat receiving portion in a power conversion apparatus for a railway vehicle, and a radiating portion installed outside the power conversion apparatus for a railway vehicle by a piping, and forcibly circulates cooling liquid in the pipe using a pump, to transport heat, and thereby obtains high cooling efficiency.

In addition, as cooling technology for an electric device, a piping and so on, other than a semiconductor module, conventionally, conventionally, there is one in which a vent hole is opened at the chassis surface of a power conversion apparatus for a railway vehicle, to take outside air into the apparatus. The temperature rise in the apparatus is suppressed using ventilation. A configuration is also quoted in which a fan is additionally provided in the power conversion apparatus for a railway vehicle with this configuration, to thereby forcibly ventilate the air inside the apparatus. Hereinafter, this conventional configuration will be described in detail.

A conventional apparatus will specifically be described using FIG. 15. FIG. 15 is a configuration diagram of a conventional liquid cooling type power conversion apparatus. A solid line arrow in FIG. 15 indicates air within an apparatus chamber 201 which a power conversion apparatus 1 takes in, and a broken line arrow indicates outside air which a cooling apparatus 100 takes in. The apparatus chamber 201 is provided in a vehicle 200, and the power conversion apparatus 1, a control device 50 such as a main transformer, and the cooling apparatus 100 are installed in the apparatus chamber 201. The vehicle 200 receives power from an overhead line 300 by a pantograph 301, and the power is supplied to a motor 303 installed on a shaft of a bogie 302, through the control device 50 and the power conversion apparatus 1, and thereby the vehicle 200 runs on a rail 304. In the power conversion apparatus 1, a plurality of semiconductor devices 2a-2f are mounted on cooling bodies 3a-3c, and inside the cooling bodies 3a-3c, flow paths 4 in which cooling liquid flows are provided and connected to a piping 7 provided in the power conversion apparatus 1. In the cooling apparatus 100, outside air is taken in from an outside air inlet 101, passes through ducts 102-106, and the outside air is exhausted from an outside air exhaust port 107. In the duct 103, an electric blower 110 is provided, and in the duct 105, a heat exchanger 111 is provided. A piping 60 connects a cooling liquid inlet 8 of the power conversion apparatus 1, the heat exchanger 111, and a pump 10 in a closed loop, and the cooling liquid circulates in this closed loop by the pump 10, to perform heat transport. That is, the heat loss generated from the semiconductor device 2 is received by the cooling body 3, the heat is transferred to the cooling liquid flowing in the flow path 4 within the cooling body 3 in a forced manner, and the heat is discharged from a radiating portion of the heat exchanger 111 in the atmosphere by the cooling liquid flowing within the piping 7, and thereby the heat loss generated from the semiconductor device 2 is effectively discharged in the atmosphere, and the temperature rise of the semiconductor device 2 can be kept within the allowable temperature range. In order for the heat exchanger 111 to improve heat exchange efficiency with the atmosphere, it is common that the heat exchanger 111 performs forced ventilation by the electric blower 110.

However, the above-described conventional power conversion apparatus for a railway vehicle has the vent hole to take in air for cooling the electric device, and thereby is not of a sealed structure. Since dust is contained in this air, there is a problem that the inside thereof may be fouled. As fouling prevention measures in the apparatus, there may be a case to install a filter over the vent hole, but the filter can not completely remove the dust, and in addition, since a filter is gradually clogged with dust, a problem arises such that maintenance such as periodically changing or cleaning the filter increases.

### BRIEF DESCRIPTION OF THE DRAWINGS

FIG. 1 is a liquid cooling type power conversion apparatus of a first embodiment;

FIG. 2 is a liquid cooling type power conversion apparatus of a second embodiment;

FIG. 3 is a liquid cooling type power conversion apparatus of a third embodiment;

FIG. 4 is a liquid cooling type power conversion apparatus of a fourth embodiment;

FIG. 5 is a liquid cooling type power conversion apparatus of a fifth embodiment;

FIG. 6 is a liquid cooling type power conversion apparatus of a sixth embodiment;

FIG. 7 is a diagram showing a configuration of a cooling system of an electric device housed in a forced circulation power conversion apparatus of a seventh embodiment;

FIG. 8 is a diagram showing a configuration of a cooling system of an electric device housed in a liquid cooling type power conversion apparatus of an eighth embodiment;

FIG. 9 is a diagram showing a configuration of a cooling system of an electric device housed in a liquid cooling type power conversion apparatus of a ninth embodiment;

FIG. 10 is a diagram showing a configuration of a cooling system of an electric device housed in a liquid cooling type power conversion apparatus of a tenth embodiment;

FIG. 11 is a diagram showing a configuration of a cooling system of an electric device housed in a liquid cooling type power conversion apparatus of an eleventh embodiment;

FIG. 12 is a diagram showing a configuration of a cooling system of an electric device housed in a liquid cooling type power conversion apparatus of a twelfth embodiment;

FIG. 13 is a diagram showing a configuration of a cooling system of an electric device housed in a liquid cooling type power conversion apparatus of a thirteenth embodiment;

FIG. 14 is a diagram showing a configuration of a cooling system of an electric device housed in a liquid cooling type power conversion apparatus of a fourteenth embodiment; and

FIG. 15 is a diagram showing a configuration of a conventional apparatus.

### DETAILED DESCRIPTION

According to an embodiment, a liquid cooling type power conversion apparatus has a power conversion apparatus and a cooling apparatus which are provided in an engine room of a railway vehicle, an electric component and a plurality of semiconductor devices which are provided in the power conversion apparatus, a third heat exchanger located between the electric component and an electric blower, a cooling body on which the plurality of the semiconductor devices are mounted, a first heat exchanger provided in the cooling apparatus, a second heat exchanger provided in the cooling apparatus having a size smaller than the first heat exchanger, a piping to connect the third heat exchanger and the second heat exchanger, and a piping to connect the cooling body and the first heat exchanger.

Hereinafter, embodiments of a liquid cooling type power conversion apparatus will be described with reference to the drawings.

### First Embodiment

(Configuration)

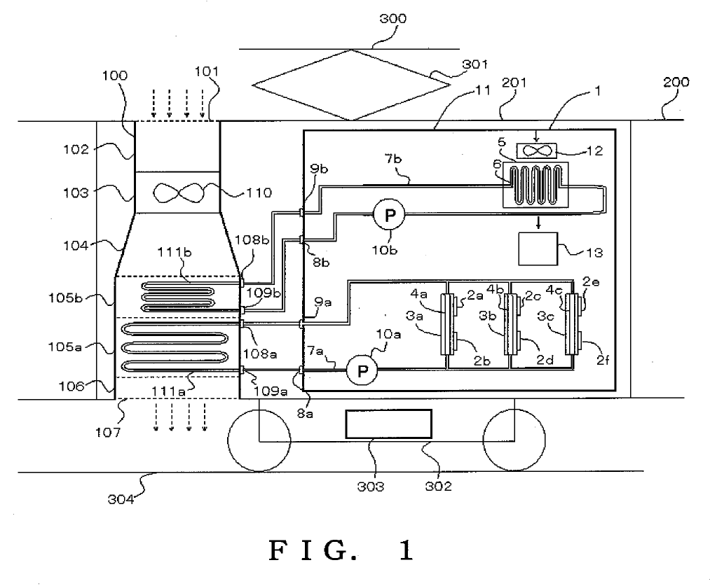

To begin with, a first embodiment will be described using FIG. 1. FIG. 1 is a diagram showing a whole configuration of a liquid cooling type power conversion apparatus. A solid line arrow in FIG. 1 indicates a flow of air within the power conversion apparatus 1, and a broken line arrow indicates a flow of outside air. The same symbols are given to the same configurations of FIG. 15 showing the conventional technology, and the duplicated description thereof will be omitted.

The solid line arrow shown in FIG. 1 indicates air within the apparatus chamber 201 which the power conversion apparatus 1 takes in, and the broken line arrow indicates outside air which the cooling apparatus 100 takes in. The apparatus chamber 201 is provided in the vehicle 200, and the power conversion apparatus 1 and the cooling apparatus 100 are installed in the apparatus chamber 201. The vehicle 200 receives power from the overhead line 300 by the pantograph 301. The received power is supplied to the motor 303 installed on the shaft of the bogie 302, through the power conversion apparatus 1. The motor 303 rotates wheels using the power as a driving force, and thereby the vehicle 200 runs on the rail 304. An electric component 13, and a plurality of the semiconductor devices 2a-2f are provided in the power conversion apparatus 1.

The electric component 13 is located in parallel with a third heat exchange 5, and the third heat exchanger 5 is located in parallel between the electric component 13 and an electric blower 12. A piping 7b of the third heat exchanger 5 is provided inside and outside thereof, and one end of the piping 7b is connected to a piping connecting portion 9b, and the other end thereof is connected to a piping connecting portion 8b through a pump 10b.

A plurality of the semiconductor devices 2a-2f are mounted on the cooling bodies 3a-3c, and flow paths 4a-4c in each of which cooling liquid flows are provided inside the cooling bodies 3a-3c, respectively. One ends of the flow paths 4a-4c are connected through a piping 7a to a piping connecting portion 9a with an outer portion connected to a chassis 11 of the power conversion apparatus 1, and the other ends thereof are connected to another piping connecting portion 8a through the piping 7a and a pump 10a. The piping 7b within the power conversion apparatus 1 connects between the cooling liquid inlet 8b of a cooling system of the electric component, the pump 10b, the third heat exchanger 5 acting as a heat receiving portion of the heat loss of the electric component 13, an electric blower 6 to forcibly send air to the third heat exchanger 5, the cooling liquid outlet 9b of the cooling system of the electric component 13, as components provided in the cooling system of the electric component.

The cooling apparatus 100 is composed of an air duct 102, an electric blower mounting portion 103, an air duct 104, heat exchanger housing portions 105a-105b. The tubular air duct 102 is at the uppermost portion and is located above the electric blower mounting portion 103. The electric blower mounting portion 103 is located at the upper portion of the air duct, and the electric blower 110 is provided inside. The air duct 104 is located above the heat exchanger housing portions 105a-105b. The heat exchanger housing portions 105a-105b are located above an air duct 106. In the heat exchanger housing portion 105b, a second heat exchanger 111b acting as a radiating portion of the heat loss of the electric component 13 in the power conversion apparatus 1 is provided, and has a heat exchanger inlet 108b for making the cooling water flow in, and a heat exchanger outlet 109b. In the heat exchanger housing portion 105a, a first heat exchanger 111a acting as a radiating portion of the heat loss of the semiconductor devices 2a-2f in the power conversion apparatus 1 is provided, and has a heat exchanger inlet 108a for making the cooling water flow in and a heat exchanger outlet 109a. The air duct 106 is located below the heat exchanger housing portions 105a-105b, and is at the lowest portion. At a ceiling portion of the air duct 102, an air inlet 101 is provided, and at a bottom portion of the air duct 106, an exhaust port 107 is provided, and each of them communicates with the outside.

The above-described cooling apparatus 100 and the power conversion apparatus 1 are connected through pipings, such that the heat exchanger inlet 108b and the cooling liquid outlet 9b, the heat exchanger outlet 109b and the cooling liquid inlet 8b, the heat exchanger inlet 108a and the cooling liquid outlet 9a, the heat exchanger outlet 109a and the cooling liquid inlet 8a are connected through the respective pipings.

(Action)

To begin with, a first temperature suppressing action in the power conversion apparatus will be described.

In the power conversion apparatus 1, the semiconductor devices 2a-2f generate heat most. The heat from the semiconductor devices 2a-2f gathers at an upper side (ceiling side) in the power conversion apparatus 1 by natural convection, and stays there. The electric blower 12 is installed at the upper portion, and the blowing direction is toward the lower side (floor portion) from the upper side. For the reason, two large air flows are generated such that the air which stays at the upper side within the power conversion apparatus 1 and contains heat flows from the upper side toward the lower side, and the air which has collided with the floor face parts right and left, and the parted airs further rise toward the upper side. For the reason, the air in the chassis 11 is caused to be diffused at any time, and accordingly, the temperature in the chassis 11 is equalized.

A next temperature suppressing action will be described. The rotation of the electric blower 12 to diffuse the above-described air inside the chassis 11 to aim temperature equalization has a temperature suppressing action of the electric component 13.

When the electric blower 12 is rotated, air is sent to the third heat exchanger 5. At this time, cooling liquid flows into a flow path 6 in a heat exchanger of the third heat exchanger 5 through the piping 7b by the pressing force of the pump 10. Air blown by the rotation of the electric blower 12 collides in the flow path 6 in a heat exchanger. The air in the chassis 11 or the air containing the heat of the semiconductor devices 2 flows along the wall surface of the flow path 6 in a heat exchanger, and thereby the heat in the air is deprived by the cooling liquid flowing in the piping. For the reason, after having passed in the flow path 6 in a heat exchanger, the air is in a state to be deprived of heat. The cooled air is blown to the electric component 13 by the electric blower 12. The blown air absorbs the heat generated in the electric component 13, and then is diffused in the chassis 11. In addition, the cooling liquid which has absorbed heat from the air in the heat exchanger 5 flows through in the piping 7b, and is sent to the second heat exchanger 111b acting as a radiating portion. The second heat exchanger 111b discharges the heat of the cooling liquid in the atmosphere by air blast from the electric blower 110. And when the cooling liquid discharges the heat and becomes again in a state not containing heat, the cooling liquid is sent again to the third heat exchanger 5. For the reason, the electric component 12 is caused to be cooled at any time by the air whose heat has been absorbed. In this manner, forced air blowing is performed by the electric blower 12 or the electric blower 110, to cause the heat exchange efficiency with air to be improved.

In addition, next, a temperature suppressing action regarding the semiconductor device 2 will be described.

The heat of the above-described semiconductor devices 2a-2f is received by the cooling bodies 3. The heat received by the cooling body 3 is transmitted to the cooling liquid which forcibly flows in the flow path 4 in a cooling body inside the cooling body 3 by the action of the pump 10a. The cooling liquid which has passed through in each of the flow paths 4a-4c in a cooling body and has absorbed heat passes through the piping 7a, and is conveyed to the first heat exchanger 111a. In the heat exchanger 111, the cooling liquid is deprived of heat by the air blast from the electric blower 111. In addition, at this time, since the second heat exchanger 111b<111a, air not containing heat collides with both the second heat exchanger 111b and the first heat exchanger 111a by the electric blower. For the reason, in the second heat exchanger 111b, it becomes possible that the heat contained in the cooling liquid is discharged in the atmosphere. And when the cooling liquid discharges the heat, and becomes again in a state not containing heat, the cooling liquid is sent again to the semiconductor devices 2a-2f. In this manner, the heat generated by the heat loss of the semiconductor devices 2a-2f is effectively discharged in the atmosphere, and thereby it is possible to keep the temperature rise of the semiconductor devices 2 within an allowable temperature range.

In addition, the action like this can be realized by making the chassis 11 to be formed of a sealed space. For the reason, since dust in the apparatus chamber 201 does not enter in the power conversion apparatus 1, the fouling degree in the power conversion apparatus 1 can be greatly improved.

(Effect)

Accordingly, with the above-described effect, the power conversion apparatus 1 is in the state of sealed structure, and the temperature rise in the chassis 11 can be suppressed approximately without fouling within the apparatus, and thereby it is possible to achieve the reliability improvement and a long life time of the power conversion apparatus 2.

In addition, in the drawing, a cooling piping system diagram in which three cooling bodies are provided for a circulation system is shown, and in many cases, the single cooling body or a plurality of the cooling bodies are connected, or a plurality of the cooling bodies are connected in parallel, but since the effect of the present embodiment is not changed in case that the number of the cooling bodies is one or a plural number, the description is made using the drawing of the case with three pieces.

### Second Embodiment

(Configuration)

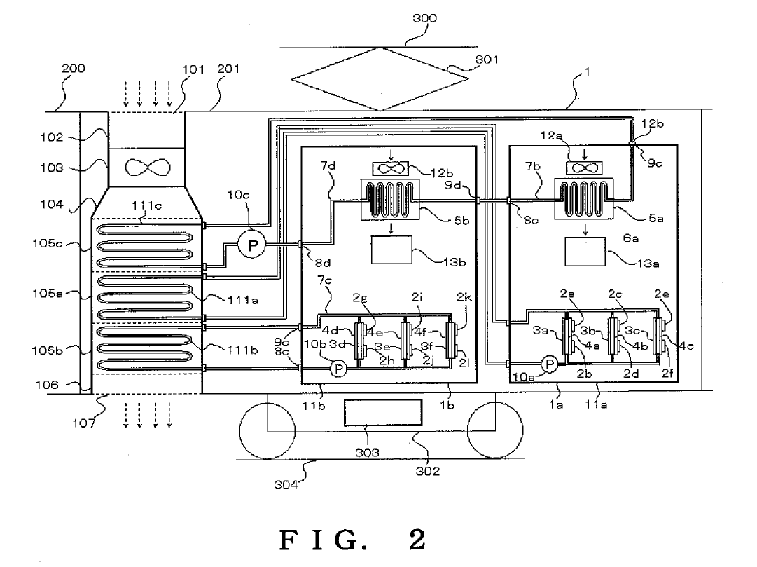

A second embodiment of a liquid cooling type power conversion apparatus will be described using FIG. 2. FIG. 2 is a diagram showing a whole configuration of the liquid cooling type power conversion apparatus. In addition, the same symbols are given to the same configurations in the first embodiment, and the duplicated description thereof will be omitted.

The point in the second embodiment which is different from the first embodiment is that a heat exchanger housing portion 105c is provided in the cooling apparatus 100, and in the heat exchanger housing portion 105c, a heat exchanger 111c is housed which acts as a radiating portion of the heat loss of an electric component 13a of a power conversion apparatus 1a, and the heat loss of an electric component 13b of a power conversion apparatus 1b.

A third heat exchanger 5a acting as a heat receiving portion of the heat loss of the electric device 13a installed in the power conversion apparatus 1a, a third heat exchanger 5b acting as a heat receiving portion of the heat loss of the electric device 13b installed in the other power conversion apparatus 1b, a pump 10c, and the heat exchange 105 in the cooling apparatus 100 are connected in the same closed loop to form a cooling system.

(Action)

The second embodiment has the same actions as the temperature suppressing actions in the power conversion apparatus and of the semiconductor device in the first embodiment.

In addition, in the second embodiment, heat exchangers 12a, 12b to cool in the power conversion apparatuses are connected in series to form the same closed loop. Since the larger the temperature difference between the cooling liquid and the air in the power conversion apparatus is, the more the heat exchange efficiency improves, the third heat exchanger 5a in the power conversion apparatus 1a with large temperature rise is arranged, after the cooling liquid passes through the third heat exchanger 5b in the power conversion apparatus 1b with small temperature rise, and thereby it is possible to effectively cool inside the power conversion apparatuses 1a, 1b.

(Effect)

Accordingly, with the above-described effect, the insides of the power conversion apparatuses 1a, 1b are connected to the same cooling system, and thereby, more space saving can be realized and the number of components can be more reduced than the case in which the cooling apparatuses 100 are separately provided for the respective power conversion apparatuses 1.

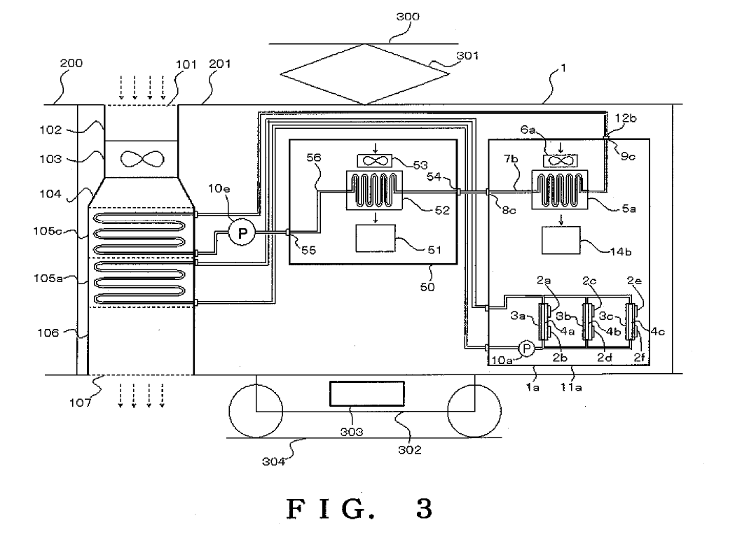

In addition, not only the power conversion apparatus 1, but, in the case as shown in FIG. 3 in which the power conversion apparatus 1 and a third heat exchanger 52 in a device (hereinafter, device box) 50 housing an electric device are connected to a heat exchanger 111g in the cooling apparatus 100 by the piping, the effect of the present embodiment can be similarly obtained without change.

### Third Embodiment

Next, a third embodiment of a liquid cooling type power conversion apparatus will be described using FIG. 4. FIG. 4 is a diagram showing a whole configuration of the liquid cooling type power conversion apparatus. The same symbols are given to the same configurations in the first to second embodiments, and duplicated description thereof will be omitted.

The point in the third embodiment which is different from the first to second embodiments is that the vehicle 200 has a plurality of the power conversion apparatuses 1a-1b. The cooling apparatus 100 has heat exchanger housing portions 105d-105g. A heat exchanger 111d acting as a radiating portion of the heat loss of the semiconductor devices 2a-2f of the power conversion apparatus 1a is housed in the heat exchanger housing portion 105d. The heat exchanger housing portion 105e is arranged above the heat exchanger housing portion 105d, and a heat exchanger 111e acting as a radiating portion of the heat loss of the electric component 13a of the power conversion apparatus 1a is housed therein. The heat exchanger housing portion 105f is arranged below the heat exchanger housing portion 105d, and a heat exchanger 111f acting as a radiating portion of the heat loss of semiconductor devices 2g-2l of the power conversion apparatus 1b is housed therein. The heat exchanger housing portion 105g is adjacent to the heat exchanger housing portion 105e, and a heat exchanger 111g acting as a radiating portion of the heat loss of the electric component 13b of the power conversion apparatus 1b is housed therein.

The above-described power conversion apparatuses 1a, 1b and the cooling apparatus 100 are connected through pipings, such that a heat exchanger inlet 108d and the cooling liquid outlet 9a, a heat exchanger outlet 109d and the cooling liquid inlet 8a, a heat exchanger inlet 108e and the cooling liquid outlet 9b, a heat exchanger outlet 109e and the cooling liquid inlet 8b, a heat exchanger inlet 108f and a cooling liquid outlet 9c, a heat exchanger outlet 109f and a cooling liquid inlet 8c, a heat exchanger inlet 108f and a cooling liquid outlet 9d, a heat exchanger outlet 109g and a cooling liquid inlet 8d are respectively connected through pipings.

(Action)

In the cooling apparatus 100, the outside air taken in from the air inlet 101 is sent to the heat exchanger 111e and the heat exchanger 111g. In the heat exchanger 111e, the outside air exchanges heat with the cooling liquid which has been warmed by the heat loss received by the air in the power conversion apparatus 1a, and thereby the temperature of the outside air rises. Similarly, in the heat exchanger 111g, the outside air exchanges heat with the cooling liquid which has been warmed by the heat loss received by the air in the power conversion apparatus 1b, and thereby the temperature of the outside air rises. The warmed outside air is sent to the heat exchanger 111d installed below the heat exchangers 111e, 111g, and exchanges heat with the cooling liquid which has been warmed by the heat loss of the semiconductor devices 2a-2f of the power conversion apparatus 1a received by the air, and thereby the temperature of the outside air rises. The further warmed outside air is sent to the heat exchanger 111f installed below the heat exchanger 111d, and exchanges heat with the cooling liquid which has been warmed by the heat loss of the semiconductor devices 2g-2l of the power conversion apparatus 1b received by the air, and thereby the temperature of the outside air rises. The outside air which has received the heat loss and has been warmed passes through the air duct 106, and is discharged from the exhaust port 107 to the outside of the vehicle 200.

(Effect)

Compared with the second embodiment, since the heat exchangers 111 are independently provided for the heat losses of the respective power conversion apparatuses 1a, 1b, the cooling efficiency thereof can be improved more than the case in which a plurality of the apparatuses are connected to the same cooling system.

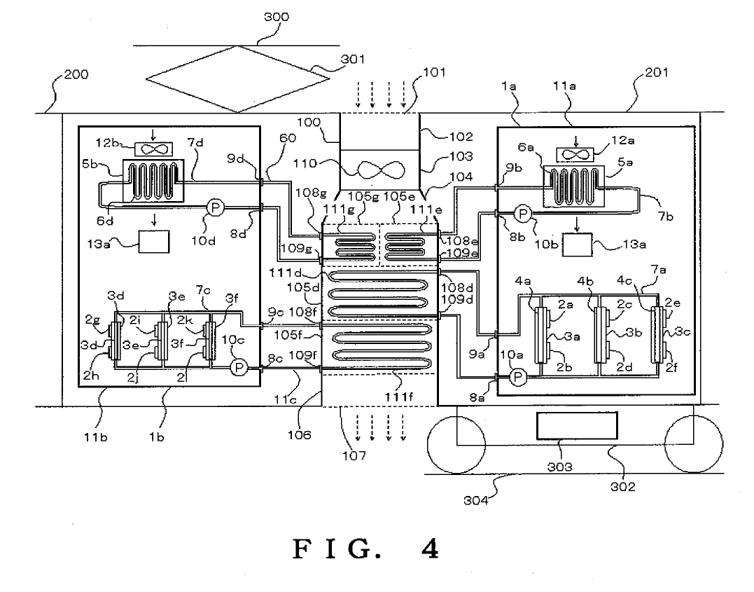

In addition, not only the power conversion apparatus 1, but, in the case as shown in FIG. 5 in which the power conversion apparatus 1 and the third heat exchanger 52 in the device (hereinafter, device box) 50 housing the electric device are connected to the heat exchanger 111g in the cooling apparatus 100 by the piping, the effect of the present embodiment can be similarly obtained without change.

### Fourth Embodiment

(Configuration)

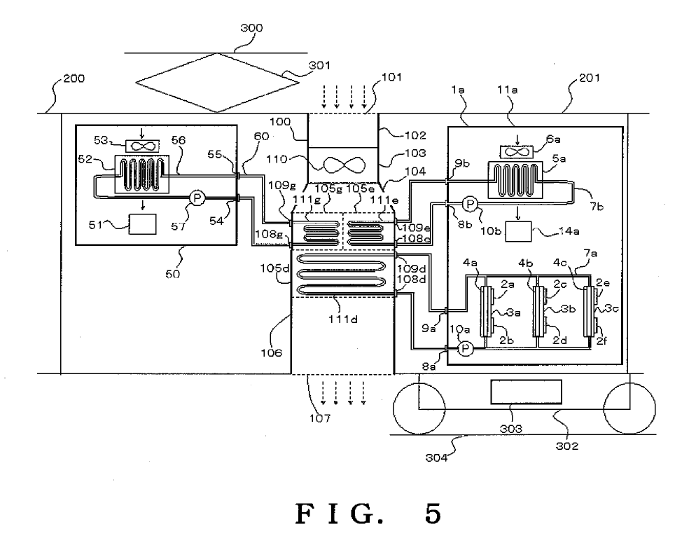

A fourth embodiment of a liquid cooling type power conversion apparatus will be described using FIG. 6. FIG. 6 is a diagram showing a configuration of a cooling system of an electric device housed in the power conversion apparatus. In addition, the same symbols are given to the same configurations in the first to third embodiments, and the duplicated description thereof will be omitted. An arrow in FIG. 6 shows a flow of air.

The point in the fourth embodiment which is different from the first embodiment is that the inside of the power conversion apparatus 1 installed on the vehicle 1 is partitioned into a chassis sealed portion 23 and a chassis opening portion 24 by the chassis 11. In the chassis sealed portion 24, the electric component 13 is located in parallel with the third heat exchange 5, and the third heat exchanger 5 is located in parallel between the electric component 13 and the electric blower 6. The piping 7b is provided inside and outside of the third heat exchanger 5, and one end of the piping 7b is connected to the piping connecting portion 9b, and the other end thereof is connected to the piping connecting portion 8b through the pump 10b. In addition, a plurality of the semiconductor devices 2a-2f are mounted on the cooling bodies 3a-3c, and the flow paths 4a-4c in each of which cooling liquid flows are provided inside the cooling bodies 3a-3c, respectively. One ends of the flow paths 4a-4c are connected through the piping 7a to the piping connecting portion 9a with the outer portion connected to the chassis 11 of the power conversion apparatus 1, and the other ends thereof are connected to the other piping connecting portion 8a through the piping 7a and the pump 10a. The chassis opening portion 24 incorporates the cooling apparatus 100 which has been installed on the vehicle 200 in the first embodiment.

(Action)

When the electric blower 12 is rotated, air is sent to the third heat exchanger 5. At this time, cooling liquid flow into the flow path 6 in a heat exchanger of the third heat exchanger 5 through the piping 7b by the pressing force of the pump 10. Air blown by the rotation of the electric blower 12 collides in the flow path 6 in a heat exchanger. The air in the chassis 11 or the air containing the heat of the semiconductor devices 2 flows along the wall surface of the flow path 6 in a heat exchanger, and thereby the heat in the air is deprived by the cooling liquid flowing in the piping. For the reason, after having passed in the flow path 6 in a heat exchanger the air is in a state to be deprived of heat. The cooled air is blown to the electric component 13 by the electric blower 12. The blown air absorbs the heat generated in the electric component 13, and then is diffused in the chassis 11. In addition, the cooling liquid which has absorbed heat from the air in the heat exchanger 5 flows through in the piping 7b, and is sent to the second heat exchanger 111b acting as a radiating portion. The second heat exchanger 111b discharges the heat of the cooling liquid in the atmosphere by air blast from the electric blower 110. And when the cooling liquid discharges the heat and becomes again in a state not including heat, the cooling liquid is sent again to the third heat exchanger 5. For the reason, the electric component 12 is caused to be cooled at any time by the air whose heat has been absorbed. In this manner, force air blowing is performed by the electric blower 12 or the electric blower 110, to cause the heat exchange efficiency with air to be improved.

In the power conversion apparatus 1, the semiconductor devices 2a-2f generate heat most. The heat stays at the upper side in the power conversion apparatus 1. The blowing direction of the electric blower 12 is toward the lower side from the upper side. For the reason, the air which stays at the upper side within the power conversion apparatus 1 and contains heat circulates by convection, and thereby the variation in temperature in the chassis 11 is equalized.

The piping 7a connects the cooling liquid inlet 8 of the power conversion apparatus 1, the heat exchanger 111, and the pump 10 in a closed loop, and the cooling liquid circulates in this closed loop by the pump 10, to perform heat transport. That is, the heat loss generated from the semiconductor device 2 is received by the cooling body 3, the heat is transferred to the cooling liquid flowing in the flow path 4 within the cooling body 3 in a forced manner, and the heat is discharged from the radiating portion of the heat exchanger 111 in the atmosphere by the cooling liquid flowing within the piping 7, and thereby the heat loss generated from the semiconductor device 2 is effectively discharged in the atmosphere, and the temperature rise of the semiconductor device 2 can be kept within the allowable temperature range.

(Effect)

Compared with the first embodiment, the cooling system is incorporated in the power conversion apparatus, and thereby the improvement of the degree of freedom in the arrangement of an apparatus and the reduction of the number of components can be achieved.

### Fifth Embodiment

(Configuration)

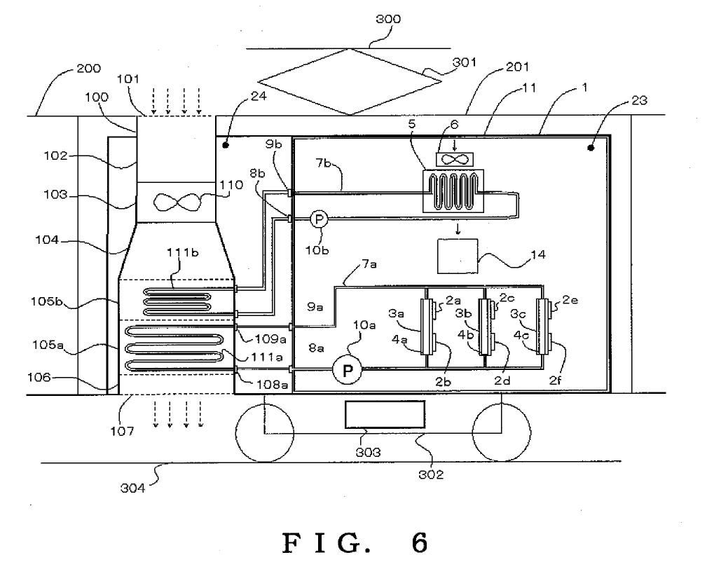

A fifth embodiment of a liquid cooling type power conversion apparatus will be described using FIG. 7. FIG. 7 is a diagram showing a configuration of a cooling system of the electric device 13 housed in the power conversion apparatus. In addition, the same symbols are given to the same configurations in the first to fourth embodiments, and the duplicated description thereof will be omitted. The configuration of FIG. 7 describes only the power conversion apparatus 1 of the first embodiment, the third heat exchanger 5 acting as a heat receiving portion of the electric device, the electric blower 12, the chassis 11, the electric component 13, and the other configuration is omitted. An arrow in FIG. 7 shows a flow of air.

In the fifth embodiment, the power conversion apparatus 1 is provided with the electric device 13, the third heat exchanger 5 acting as the heat receiving portion of the electric device 13, the flow path 6 in a heat exchanger, the electric blower 2, the chassis 11, and a duct 14. The electric blower 12 and the third heat exchanger 5 are arranged in parallel, and the duct 14 is laid on the third heat exchanger 5 at the side opposite to the electric blower 12. The electric component 13 is arranged in the vicinity of a blowoff port of the duct 14.

(Action)

When the electric blower 12 rotates, the air which has been warmed by the heat loss of the electric component 13 is sent to the third heat exchanger 5. The air exchanges heat with the cooling liquid in the third heat exchanger 5 and is cooled, and the cooled air is directly ventilated to the electric component 13 through the duct 14.

(Effect)

Compared with the first embodiment, since the cooled air can be directly ventilated to the electric component 13, the cooling efficiency of the electric component 13 is improved.

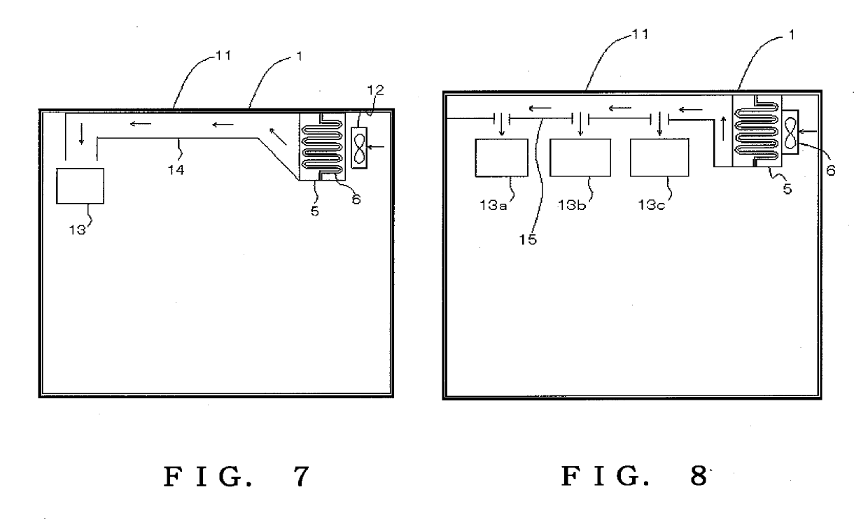

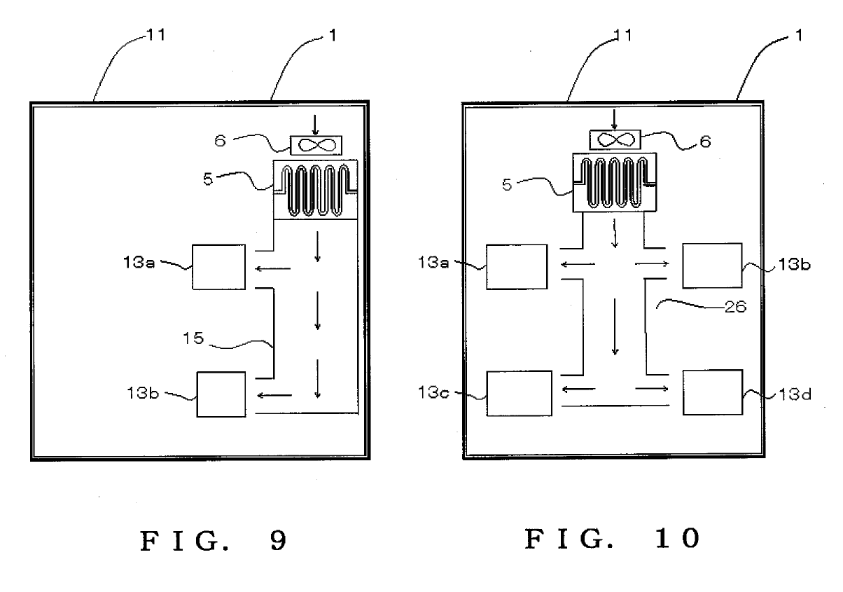

In addition, in case that a plurality of electric components 13a - 13c which are arranged in parallel as shown in FIG. 8 are to be cooled, such a case can be dealt with by changing the blowoff ports of the duct 14, without changing the effect of the present embodiment. As other application examples, FIG. 9 shows a case to cool electric components which are vertically arranged in parallel, and FIG. 10 shows a case to cool electric components which are arranged vertically and horizontally. In any cases of FIGS. 8-10, the effect of the fifth embodiment can be obtained without change.

### Sixth Embodiment

(Configuration)

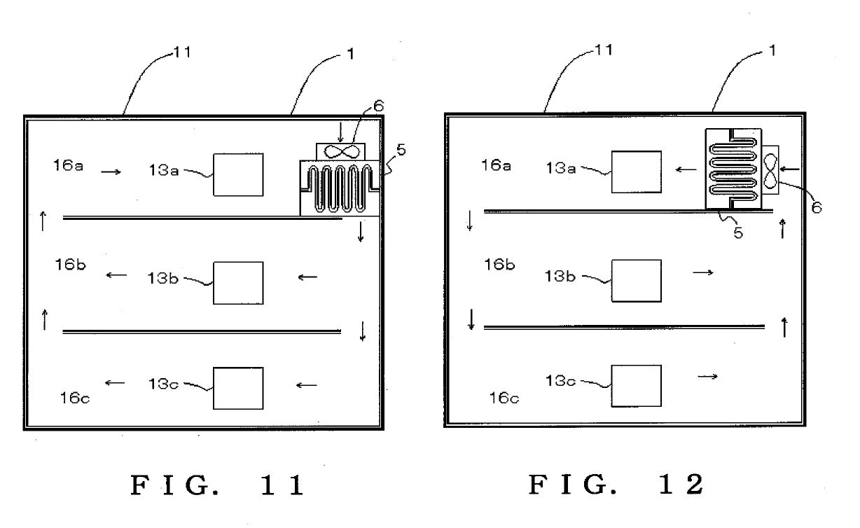

A sixth embodiment of a liquid cooling type power conversion apparatus will be described using FIG. 11. FIG. 11 is a diagram showing a configuration of a cooling system of the electric device 13 housed in the power conversion apparatus 1. In addition, the same symbols are given to the same configurations in the first to fifth embodiments, and the duplicated description thereof will be omitted. The configuration of FIG. 11 describes only the power conversion apparatus 1 of the first embodiment, the electric device 13, the third heat exchanger 5 acting as a heat receiving portion of the electric device 13, the flow path 6 in a heat exchanger, the electric blower 12, the chassis 11, the electric components 13a-13c, and the other configuration is omitted. An arrow in FIG. 11 shows a flow of air.

In the sixth embodiment, the power conversion apparatus 1 has the chassis 11 which is partitioned into blocks 16a-16c by partition boards. The electric component 13a, the electric component 13b, and the electric component 13c are respectively housed in the block 16a, the block 16b, and the block 16c.

(Action)

When the electric blower 12 rotates, the air which has been warmed by the heat loss of the electric components 13 is sent to the third heat exchanger 5. The air exchanges heat with the cooling liquid in the third heat exchanger 5, and is cooled. Since wind generated by the electric blower 12 blows from above to below, the air cooled by the heat exchange diffuses into the blocks 16a-16c by the convection in the chassis 11. The electric components 13a-13c housed in the respective blocks 16a-16c are cooled by the cooled air.

(Effect)

Since the forced ventilation to the third heat exchanger 5 acting as a heat receiving portion of the electric device by the electric blower 12 is directly performed to the electric device or the module having much heat loss, it is possible to achieve the reliability improvement and a long life time of the electric device or the module which has been subjected to the forced ventilation, and it is possible to suppress the thermal influence to the other device and the module.

In addition, in the drawing, the chassis partition boards 16a-16b are shown by two, and the blocks 13a-13c are shown by three, but since the effect of the present embodiment is not changed in case that the number of them is one or a plural number, the description is made using the drawing of the case with the two partition boards, and the three blocks.

As an application example thereof, in case that the electric component 13a housed in the block 16a as shown in FIG. 12 is to be cooled particularly, such cooling becomes possible by vertically installing the electric blower 12. In the case of FIG. 12, the effect of the sixth embodiment can be obtained without change.

### Seventh Embodiment

(Configuration)

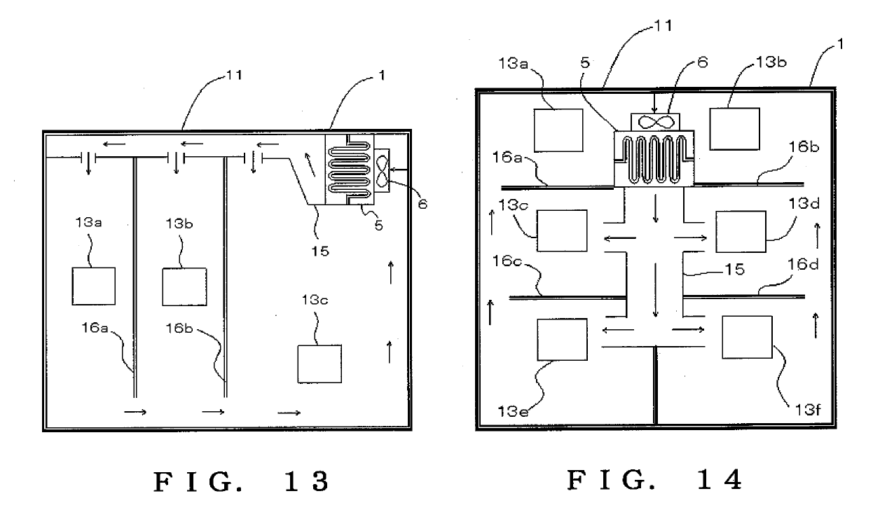

A seventh embodiment of a liquid cooling type power conversion apparatus will be described using FIG. 13. FIG. 13 is a diagram showing a configuration of a cooling system of the electric device housed in the power conversion apparatus. In addition, the same symbols are given to the same configurations in the first to sixth embodiments, and the duplicated description thereof will be omitted. The configuration of FIG. 13 describes only the power conversion apparatus 1 of the first embodiment, the third heat exchanger 5 acting as a heat receiving portion of the electric device, the flow path 6 in a heat exchanger, the electric blower 12, the chassis 11, the electric components 13, and the duct 14, and the other configuration is omitted. An arrow in FIG. 13 shows a flow of air.

The point in the seventh embodiment which is different from the sixth embodiment is that, in the power conversion apparatus 1, the duct 14 is laid on the portion which partitions the chassis 11 into the blocks 16a-16c by providing a plurality of partition boards, and blowoff ports of the duct 14 are provided for the respective blocks 16a-16c.

(Action)

When the electric blower 12 rotates, the air which has been warmed by the heat loss of the electric component 13 is sent to the third heat exchanger 5. The air exchanges heat with the cooling liquid in the third heat exchanger 5, and is cooled. The wind generated by the electric blower 12 passes through the duct 14, and is sent to the blocks 16a-16c. Since the sent cooled air is colder and heavier than the airs in the blocks 16a-16c, the cooled air falls downward from the blowoff ports of the duct 14. The fallen air cools the electric components 13a-13c. Since the spaces in the respective blocks 16a-16c are interconnected in the downward gap of the partition boards, the air flows toward the block 16c where the electric blower 12 is provided. Accordingly, the air in the power conversion apparatus 1 circulates by convection.

(Effect)

Since the air by the forced ventilation to the third heat exchanger 5 acting as a heat receiving portion of the electric devices 13 by the electric blower 12 is sent to the plurality of blocks 16a-16c, the convection of the air is generated, and thereby the temperature in the power conversion apparatus 1 can be suppressed within a prescribed value, and it is possible to achieve the reliability improvement and a long life time.

In addition, in the drawing, the chassis partition boards 16a-16b are shown by two, and the blocks 13a-13c are shown by three, but the effect of the present embodiment is not changed in case that the number of them is one or a plural number, the description is made using the drawing of a case with the two partition boards, and the three blocks.

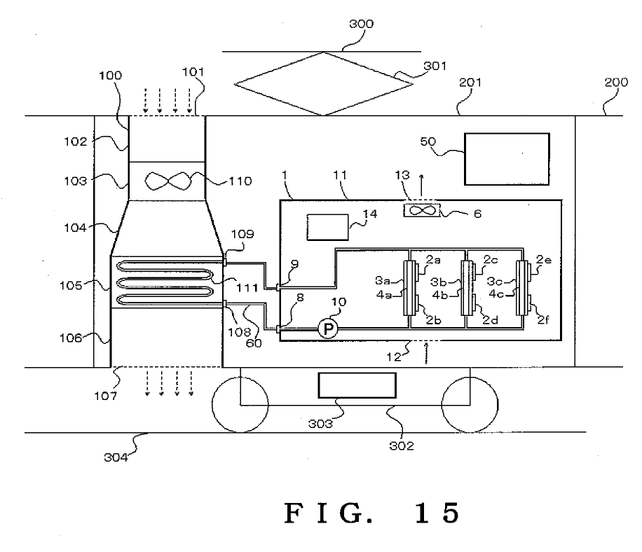

As an application example, the duct 14 is installed at the center in the chassis 11, and thereby it is possible to cool not only the blocks which are arranged in parallel in the horizontal direction, but also the blocks which are arranged in parallel in the vertical direction similarly. In the case of FIG. 14, the effect of the seventh embodiment can be obtained without change.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A liquid cooling type power conversion apparatus, comprising:
a power conversion apparatus and a cooling apparatus which are provided in an engine room of a railway vehicle;
an electric component and a plurality of semiconductor devices which are provided in the power conversion apparatus;
a third heat exchanger located between the electric component and an electric blower in the power conversion apparatus;
a cooling body on which the plurality of the semiconductor devices are mounted;
a first heat exchanger provided in the cooling apparatus;
a second heat exchanger provided in the cooling apparatus having a size smaller than the first heat exchanger;
a piping for the third heat exchanger to connect the third heat exchanger and the second heat exchanger; and
a piping for a cooling body to connect the cooling body and the first heat exchanger.

2. The liquid cooling type power conversion apparatus as recited in claim 1, wherein:
a plurality of the power conversion apparatuses are provided in the engine room;
the electric components are respectively provided for insides of the plurality of power conversion apparatuses;
the electric component, the electric blower, and the third heat exchanger are arranged on an approximately same straight line; and
the plurality of the third heat exchangers respectively provided in the plurality of the power conversion apparatuses, and the second heat exchanger provided in the cooling apparatus are connected through the piping for the third heat exchanger.

3. The liquid cooling type power conversion apparatus as recited in claim 2, wherein:
a plurality of the second heat exchangers are arranged in parallel in the cooling apparatus, so as to divide an inside of the cooling apparatus.

4. The liquid cooling type power conversion apparatus as recited in claim 3, further comprising:
a duct provided on the third heat exchanger at a side opposite to the electric blower;
wherein the electric component is arranged in the vicinity of a blowoff port of the duct.

5. The liquid cooling type power conversion apparatus as recited in claim 1, wherein:
the electric blower is installed at an upper portion in the power conversion apparatus, the third heat exchanger is installed at a lower side in the power conversion apparatus, and the electric component is arranged below the third heat exchanger.

6. A liquid cooling type power conversion apparatus, comprising:
a chassis opening portion with an opening portion which is provided in a railway vehicle;
a chassis sealed portion which is sealed and is provided in the railway vehicle;
a cooling apparatus installed in the chassis opening portion;
a third heat exchanger located between an electric blower and an electric component in the chassis sealed portion;
a cooling body on which a plurality of semiconductor devices are mounted in the chassis sealed portion;
a first heat exchanger provided in the cooling apparatus;
a second heat exchanger provided in the cooling apparatus having a size smaller than the first heat exchanger;
a piping for the third heat exchanger to connect the third heat exchanger and the second heat exchanger; and
a piping for a cooling body to connect the cooling body and the first heat exchanger.

7. The liquid cooling type power conversion apparatus as recited in claim 6, wherein:
a plurality of the chassis sealed portions are provided;
the electric components are respectively provided for insides of the plurality of chassis sealed portions;
the electric component, the electric blower, and the third heat exchanger are arranged on an approximately same straight line; and
the plurality of the third heat exchangers respectively provided in the plurality of the chassis sealed portions, and the second heat exchanger provided in the cooling apparatus are connected through the piping for the third heat exchanger.

8. The liquid cooling type power conversion apparatus as recited in claim 6, wherein:
a plurality of the second heat exchangers are arranged in parallel in the cooling apparatus, so as to divide an inside of the cooling apparatus.

9. The liquid cooling type power conversion apparatus as recited in claim 6, further comprising:
a duct provided to the third heat exchanger at a side opposite to the electric blower;
wherein the electric component is arranged in the vicinity of a blowoff port of the duct.

10. The liquid cooling type power conversion apparatus as recited in claim 6, wherein:
the electric blower is installed at an upper portion in the chassis sealed portion, the third heat exchanger is installed at a lower side in the chassis sealed portion, and the electric component is arranged below the third heat exchanger.

11. A railway vehicle, comprising:
a power conversion apparatus provided in an engine room to convert power supplied from an overhead line;
an electric component and a semiconductor device which are provided in the power conversion apparatus;
a third heat exchanger arranged in the power conversion apparatus for cooling the electric component;
a cooling body for cooling the semiconductor device;
a cooling apparatus to cool a medium for cooling an inside of the power conversion apparatus provided in the engine room;
a first heat exchanger which is provided in the cooling apparatus and is connected to the cooling body;
a second heat exchanger which is provided in the cooling apparatus and is connected to the third heat exchanger, and has a size smaller than the first heat exchanger; and
a motor which is driven by the power converted by the power conversion apparatus.

12. The railway vehicle as recited in claim 11, further comprising:
an electric blower which sends air to the third heat exchanger, and cools the electric component by the sent air.

13. The railway vehicle as recited in claim 12, wherein:
the electric component ,the electric blower, and the third heat exchanger are arranged on an approximately same straight line.

14. The railway vehicle as recited in claim 12, further comprising:
a duct provided to the third heat exchanger at a side opposite to the electric blower;
wherein the electric component is arranged in the vicinity of a blowoff port of the duct.

15. The railway vehicle as recited in claim 11, wherein:
the second heat exchanger is arranged at a amore upstream side than the first heat exchanger along a direction of an air flow.

16. The railway vehicle as recited in claim 13, wherein:
the electric blower is installed at an upper portion in the power conversion apparatus; and
the electric blower, the third heat exchanger, and the electric component are arranged in this order along a direction of an air flow by the electric blower.

17. The railway vehicle as recited in claim 11, wherein:
the semiconductor device and the cooling body are arranged below the electric component.

18. The railway vehicle as recited in claim 11, wherein:
a plurality of the power conversion apparatuses are provided in the engine room;
the electric components and the third heat exchangers are respectively provided for insides of the plurality of power conversion apparatuses; and
the plurality of the third heat exchangers are connected to the second heat exchanger provided in the cooling apparatus.

19. The railway vehicle as recited in claim 11, wherein:
a plurality of the second heat exchangers are provided, and are respectively connected to the plurality of the third heat exchangers.

20. The railway vehicle as recited in claim 19, wherein:
a plurality of the second heat exchangers are arranged in parallel in the cooling apparatus, so as to divide an inside of the cooling apparatus.
